(19) United States
(12) Patent Application Publication
(10) Pub. No.: US 2014/0332268 A1
(43) Pub. Date: Nov. 13, 2014

(54) Cable Resisting Noise through Wave Absorption

(71) Applicant: Chun-Hsing Wu, Taipei (TW)

(72) Inventor: Chun-Hsing Wu, Taipei (TW)

(21) Appl. No.: 13/973,055

(22) Filed: Aug. 22, 2013

(30) Foreign Application Priority Data
May 9, 2013 (TW) 102208798

(51) Int. Cl. H05K 9/00; H01B 7/02

(52) U.S. Cl. CPC H05K 9/00; H01B 7/0225
USPC 174/74 R

(57) ABSTRACT

The present invention is a noise-resistant cable. Connectors are used to connect different electronic equipments for data transmission. A wave-absorbing layer is used to protect signals from interference of the electronic equipments. Thus, interference is effectively resisted; signals are stabilized; and, electronic equipments are prevented from electromagnetic interference and leakage generated by cable.

### TECHNICAL FIELD OF THE INVENTION

The present invention relates to a noise-resistant cable; more particularly, relates to using connectors to connect different electronic equipments for data transmission and using a wave-absorbing layer to protect signals from interference of the electronic equipments, where interference is effectively resisted, signals are stabilized and electronic equipments are prevented from electromagnetic interference and leakage generated by cable.

### DESCRIPTION OF THE RELATED ART

A general cable comprises a set of wires and two connecters located at two ends of the wires. Each of the wires comprises a core wire, a bonding braid covered on the core wire and a wire sheath covered on the bonding braid. The connecters are connected with the core wires. Thus, data are transferred between electronic equipments through the cable.

However, the cable uses the bonding braid for ground and noise protection, only. When the connectors connect the electronic equipments for data transmission (especially at a speed of 1 billion-plus bits per second), signals may be easily interfered by the cable and the electronic equipments; and, thus, states of signals become unstable, transmission performance is worsened and wireless devices are affected by electronic radiation of cable.

Hence, the prior art does not fulfill all users' requests on actual use.

### SUMMARY OF THE INVENTION

The main purpose of the present invention is to use connectors to connect different electronic equipments for data transmission and to use a wave-absorbing layer to protect signals from interference of the electronic equipments, where interference is effectively resisted, signals are stabilized and electronic equipments are prevented from electromagnetic interference and leakage generated by cable.

To achieve the above purpose, the present invention is a cable resisting noise through wave absorption, comprising a cable wire and at least two connectors, where the cable wire comprises a plurality of core wires; a bonding braid covered on the core wires; a wave-absorbing layer covered on the bonding braid; and a wire sheath covered on the wave-absorbing layer; the connectors are separately connected with two ends of the cable wire; and each of the connectors comprises a rubber core; a plurality of pins disposed on the rubber core and separately connected with the core wires; a metal shell covered on the rubber core and contacted with the bonding braid; and a plastic shell covered on the metal shell. Accordingly, a novel cable resisting noise through wave absorption is obtained.

### BRIEF DESCRIPTIONS OF THE DRAWINGS

The present invention will be better understood from the following detailed description of the preferred embodiment according to the present invention, taken in conjunction with the accompanying drawings, in which

FIG. 1 is the perspective view showing the preferred embodiment according to the present invention;

FIG. 2 is the explosive view showing the preferred embodiment; and

FIG. 3 is the sectional view showing the cable wire.

### DESCRIPTION OF THE PREFERRED EMBODIMENT

The following description of the preferred embodiment is provided to understand the features and the structures of the present invention.

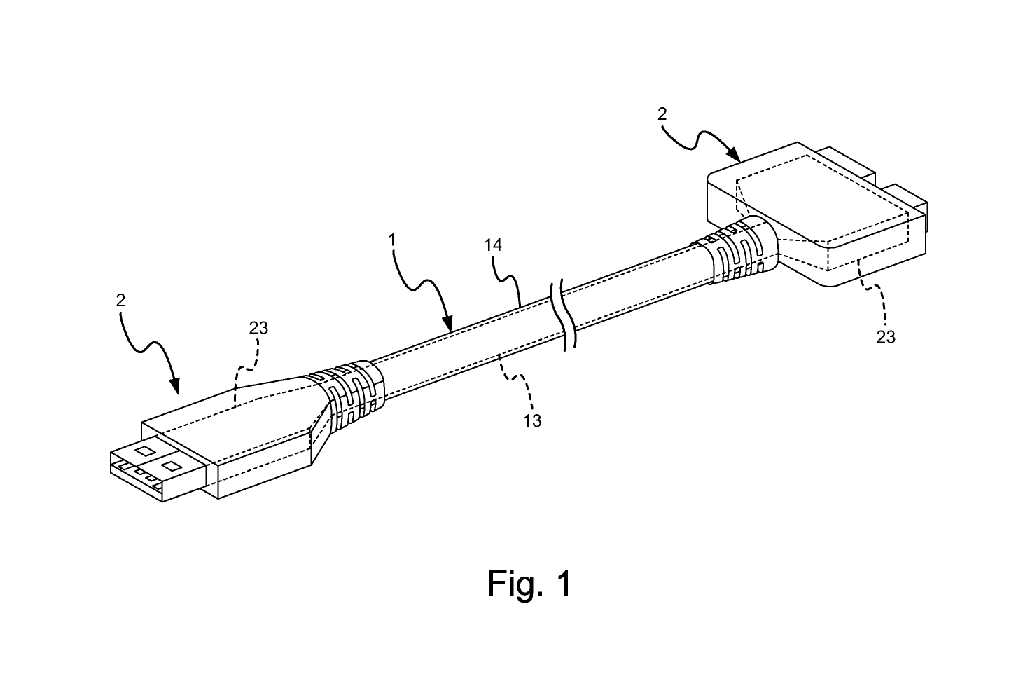

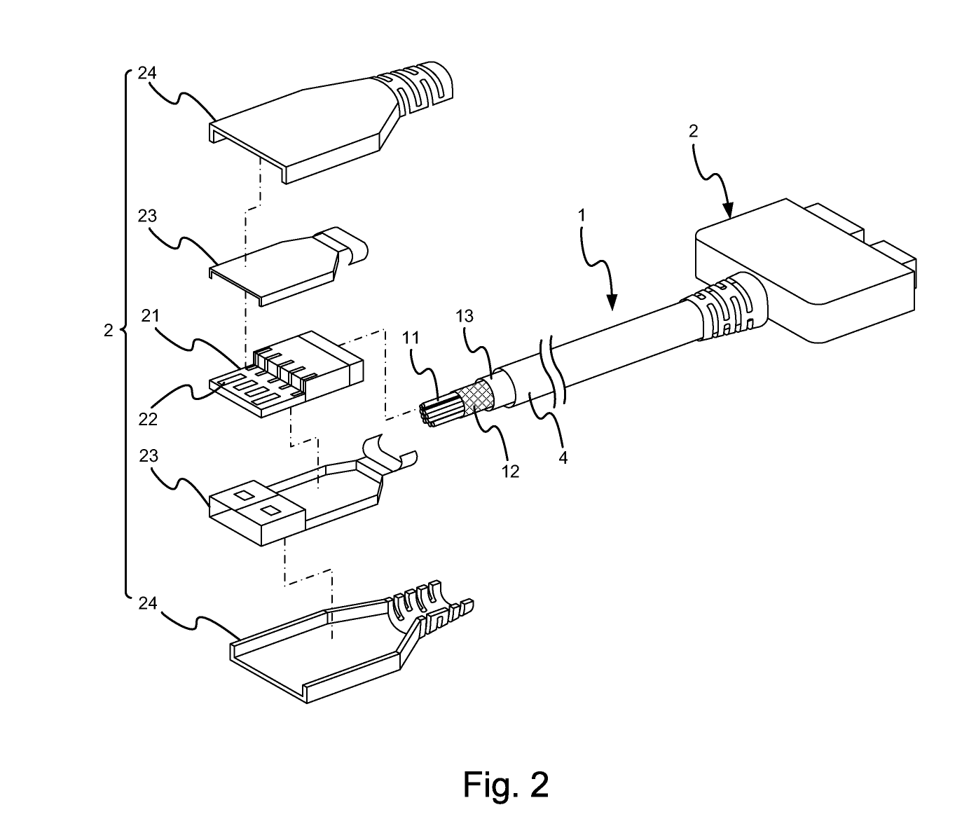

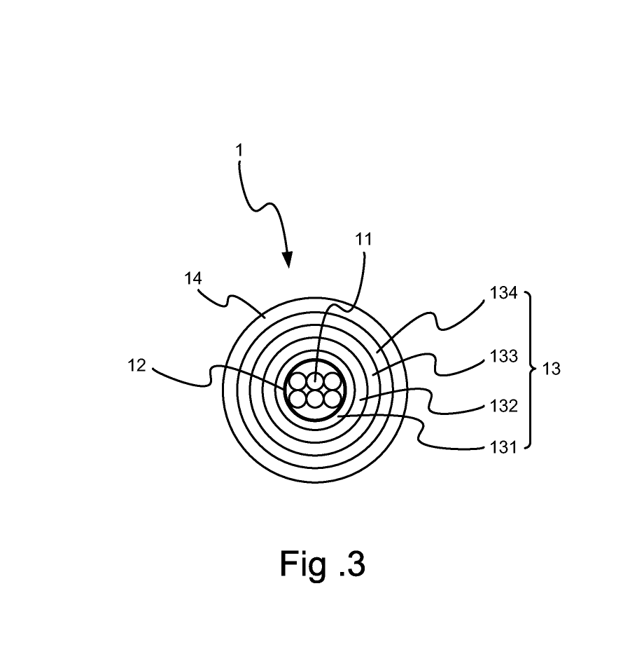

Please refer to FIG. 1 to FIG. 3, which are perspective and explosive views showing a preferred embodiment according to the present invention; and a sectional view showing a cable wire. As shown in the figures, the present invention is a cable resisting noise through wave absorption, comprising a cable wire 1 and at least two connectors 2.

The cable wire 1 comprises a plurality of core wires 11; a bonding braid 12 covered on the core wires 11; a wave-absorbing layer 13 covered on the bonding braid 12; and a wire sheath 14 covered on the wave-absorbing layer 13. The wave-absorbing layer 13 comprises a polyethylene film 131 layered on the bonding braid 12; a nylon film 132 layered on the polyethylene film 131; a metal film 133 layered on the nylon film 132; and a polyester film 134 layered on the metal film 133. Therein, the nylon film 132 is temperature-resistant at −50˜100 Celsius degrees (° C.); and, the polyester film 134 is made of polyethylene terephthalate (PET).

The connectors 2 are separately connected with two ends of the cable wire 1. Each of the connectors 2 comprises a rubber core 21; a plurality of pins 22 disposed on the rubber core 21 and separately connected with the core wires 11; a metal shell 23 covered on the rubber core 21 and contacted with the bonding braid 12; and a plastic shell 24 covered on the metal shell 23.

Thus, a novel cable resisting noise through wave absorption is obtained.

On using the present invention, the connectors 2 connect different electronic equipments for data transmission (not shown in the figures.) Through setting the wave-absorbing layer 13 comprising the polyethylene film 131, the nylon film 132, the metal film 133 and the polyester film 134, signals are protected from interference of the electronic equipments during data transmission. Therein, the polyethylene film 131 is non-toxic, acid-resistant, alkali-resistant, water-resistant and elecinsulating; the nylon film 132 is non-toxic, transmittable, wear-resistant, puncture-resistant, oil-resistant, high/low-temperature-resistant and highly-extensible; the metal film 133 is highly-conductive and wave-penetration-resistant; and, the polyester film 134 is tenacious, wear-resistant, electro-insulative, anti-stretchable and impact-resistant. Thus, when the connectors 2 transfer data with the coordination of the cable wire 1, the wave-absorbing layer 13 is used to protect signals from interference of the electronic equipments, where interference is effectively resisted; signals are stabilized; and electronic equipments are prevented from electromagnetic interference and leakage generated by cable.

To sum up, the present invention is a cable resisting noise through wave absorption, where connectors are used to connect different electronic equipments for data transmission and, by using a wave-absorbing layer, signals are protected from interference of the electronic equipments; and, thus, interference is effectively resisted, signals are stabilized and electronic equipments are prevented from electromagnetic interference and leakage generated by cable.

The preferred embodiment herein disclosed is not intended to unnecessarily limit the scope of the invention. Therefore, simple modifications or variations belonging to the equivalent of the scope of the claims and the instructions disclosed herein for a patent are all within the scope of the present invention.

What is claimed is:

1. A cable resisting noise through wave absorption, comprising
a cable wire, said cable wire comprising
a plurality of core wires;
a bonding braid, said bonding braid being covered on said core wires;
a wave-absorbing layer, said wave-absorbing layer being covered on said bonding braid; and
a wire sheath, said wire sheath being covered on said wave-absorbing layer; and
at least two connectors, said connectors being separately connected with two ends of said cable wire, each of said connectors comprising
a rubber core;
a plurality of pins, said pins being disposed on said rubber core, said pins being separately connected with said core wires;
a metal shell, said metal shell being covered on said rubber core, said metal shell being contacted with said bonding braid; and
a plastic shell, said plastic shell being covered on said metal shell.

2. The cable according to claim 1,
wherein said wave-absorbing layer comprises
a polyethylene film, said polyethylene film being layered on said bonding braid;
a nylon film, said nylon film being layered on said polyethylene film;
a metal film, said metal film being layered on said nylon film; and
a polyester film, said polyester film being layered on said metal film.

3. The cable according to claim 2,
wherein said nylon film is temperature-resistant at −50˜100 Celsius degrees (° C.).

4. The cable according to claim 2,
wherein said polyester film is made of polyethylene terephthalate (PET).
